(19) United States
(12) Patent Application Publication
(10) Pub. No.: US 2025/0036823 A1
(43) Pub. Date: Jan. 30, 2025

(54) METHOD AND DEVICE FOR GENERATING OUTPUT DATA OF VIRTUAL SENSOR

(71) Applicant: Samsung Electronics Co., Ltd., Suwon-si (KR)

(72) Inventors: Maksim Alekseevich VILENSKII, Moscow (RU); Oleg Vladimirovich OGURTSOV, Moscow district (RU); Artem Aleksandrovich LUKANIN, Moscow district (RU); Vitaly Andreevich CHEREPANOV, Perm district (RU); Aleksander Vladimirovich BORZILOV, Moscow (RU); Vladimir Alekseevich EREMEEV, Moscow (RU); Jonghyun HO, Suwon-si (KR); Unkyu PARK, Suwon-si (KR)

(21) Appl. No.: 18/675,744

(22) Filed: May 28, 2024

(30) Foreign Application Priority Data
Jul. 24, 2023 (RU) 2023119410

(51) Int. Cl. G06F 30/13; G06F 30/27

(52) U.S. Cl. CPC G06F 30/13; G06F 30/27

(57) ABSTRACT

The disclosure relates to robotics, computer vision, scanning of three-dimensional (3D) objects, navigation, and, in particular, to a method and device for generating output data of a virtual sensor. A technical result is to increase the accuracy of matching the generated output data of the virtual sensor with the output data of the particular real sensor. A method for generating output data of the virtual sensor is provided. The method includes simulating a three-dimensional (3D) virtual space corresponding to a real space, objects having object parameters and the virtual sensor in the simulated 3D virtual space, defining environment conditions of the simulated objects and relative position of the simulated objects in the simulated 3D virtual space and generating the output data of the virtual sensor based on the simulated virtual sensor.

### CROSS-REFERENCE TO RELATED APPLICATION(S)

This application is based on and claims priority under 35 U.S.C. § 119 (a) of a Russian patent application number 2023119410, filed on Jul. 24, 2023, in the Russian Intellectual Property Office, the disclosure of which is incorporated by reference herein in its entirety.

### BACKGROUND

### 1. Field

The disclosure relates to robotics, computer vision, scanning of three-dimensional (3D) objects, navigation. More particularly, the disclosure relates to a method and device for generating output data of a virtual sensor.

### 2. Description of Related Art

For different applications, it is necessary to collect data from different sensors in different spaces, such as rooms, open spaces, etc., which include different sets of objects. However, the preparation of many such real spaces is a difficult, very long duration and expensive task. It is much easier and faster to generate any number of virtual spaces with the required sets of objects, to generate virtual sensors and, in virtual spaces, to obtain data of the virtual sensors that can be used for various applications, such as, for example, virtual/augmented reality devices, navigation devices, simultaneous localization and mapping (SLAM) devices, object recognition devices, etc., including for use as training data for various devices based on artificial intelligence (AI) models.

At present, an approach is widely used in which the virtual spaces and the virtual sensors are generated to obtain the required data. However, the developed solutions do not take into account all parameters, at least such as inaccuracies of measurement/output data of real sensors, materials of objects, angles of incidence of sensor signals, changes in sensor signals when they interact with a mirror (recognition of a mirror or reflecting objects), passage of sensor signals through transparent objects (recognition of transparent objects) and propagation of a signal that has more than one object in its path.

In the related art, technical solutions for generating the output data of the virtual sensor using the virtual space are known.

U.S. Patent Application US 2021/0072397 A1 published on Mar. 11, 2021 and titled as “GENERATION OF SYNTHETIC LIDAR SIGNALS” proposes a generator for generating three-dimensional point clouds of synthetic LIDAR signals from a set of real physical signals. Model includes a random generator and a machine learning system (neural network). However, this technical solution does not take into account materials of objects, the angles of incidence of a sensor signal, and this technical solution does not operate in real time.

U.S. Patent Application US 2020/0301799 A1 published on Sep. 24, 2020 and titled as “SYSTEMS AND METHODS FOR GENERATING SYNTHETIC SENSOR DATA VIA MACHINE LEARNING” proposes systems and methods that combine physics-based systems with machine learning to generate synthetic LIDAR data that accurately mimics a real-world system. However, this technical solution does not take into account errors in depth estimation, standard noise, materials of objects.

U.S. Patent Application US 2018/0203445 A1 published on Jul. 19, 2018 and titled as “GENERATING SIMULATED SENSOR DATA FOR TRAINING AND VALIDATION OF DETECTION MODELS” proposes a general pipeline of generating data for training and validation. The pipeline includes simulating perception of 3D model by several sensors, including LIDAR. Simulated sensor outputs may include artificial noise added for realism. However, this technical solution does not disclose the training of a virtual sensor on the signals received by the real sensor from different objects.

U.S. Patent Application US 2019/0303759 A1 published on Oct. 3, 2019 and titled as “TRAINING, TESTING, AND VERIFYING AUTONOMOUS MACHINES USING SIMULATED ENVIRONMENTS” proposes a technical solution in which a simulator and virtual sensors are used to process output data of a deep neural network trained on real data. However, this technical solution does not disclose the training of a virtual sensor on the signals received by the real sensor from different objects.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a method and device for generating output data of a virtual sensor that match with output data of a particular real sensor. At the same time, the method and device for generating the output data of the virtual sensor are capable to increase the accuracy of matching generated output data of the virtual sensor with the output data of the particular real sensor.

Additional aspects will be set forth in part in the description which follows and, in part, will be apparent from the description, or may be learned by practice of the presented embodiments.

According to an embodiment of the disclosure, a method performed by an electronic device for generating output data of a virtual sensor is provided. The method may include simulating, by the electronic device, a three-dimensional (3D) virtual space corresponding to a real space, objects having object parameters comprised in the 3D virtual space and the virtual sensor in the simulated 3D virtual space, the virtual sensor corresponding to a real sensor. The method may include defining, by the electronic device, environment conditions of the simulated objects and relative position of the simulated objects in the simulated 3D virtual space. The method may include generating, by the electronic device, the output data of the virtual sensor by using the simulated virtual sensor based on at least one of the environment conditions the relative position and an inaccuracy of the output of the real sensor, wherein the output data includes at least one of the object parameters, the relative position of the objects and the virtual sensor, and movement of the objects and the virtual sensor.

According to an embodiment of the disclosure, the electronic device for generating output data of a virtual sensor is provided. In an embodiment, the electronic device comprise memory storing one or more computer programs and a trained artificial intelligence (AI) model of the virtual sensor and one or more processors. In an embodiment, the one or more computer programs include computer-executable instructions that, when executed by the one or more processors, cause the electronic device to simulate a three-dimensional (3D) virtual space corresponding to a real space, objects having object parameters comprised in the 3D virtual space and the virtual sensor in the simulated 3D virtual space, the virtual sensor corresponding to a real sensor. In an embodiment, the one or more computer programs include computer-executable instructions that, when executed by the one or more processors, cause the electronic device to define environment conditions of the simulated objects and relative position of the simulated objects in the simulated 3D virtual space. In an embodiment, the one or more computer programs include computer-executable instructions that, when executed by the one or more processors, cause the electronic device to generate output data of the virtual sensor by using the simulated virtual sensor based on at least one of the environment conditions the relative position and an inaccuracy of the output of the real sensor, wherein the output data includes at least one of the object parameters, the relative position of the objects and the virtual sensor, and movement of the objects and the virtual sensor.

According to an embodiment of the disclosure, one or more non-transitory computer-readable storage media storing one or more computer programs including computer-executable instructions that, when executed by one or more processors of an electronic device, cause the electronic device to perform the method is provided. The method may include simulating, by the electronic device, a three-dimensional (3D) virtual space corresponding to a real space, objects having object parameters comprised in the 3D virtual space and the virtual sensor in the simulated 3D virtual space, the virtual sensor corresponding to a real sensor. The method may include defining, by the electronic device, environment conditions of the simulated objects and relative position of the simulated objects in the simulated 3D virtual space. The method may include generating, by the electronic device, the output data of the virtual sensor by using the simulated virtual sensor based on at least one of the environment conditions the relative position and an inaccuracy of the output of the real sensor, wherein the output data includes at least one of the object parameters, the relative position of the objects and the virtual sensor, and movement of the objects and the virtual sensor.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart of a method for generating output data of a virtual sensor according to an embodiment of the disclosure; and

FIG. 2 is a block diagram of a device for generating output data of a virtual sensor according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to bibliographic meanings, but are merely used by the inventors of the to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It should be understood that the singular form “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory or the one or more computer programs may be divided with different portions stored in different multiple memories.

It should be understood that although the terms “first”, “second”, etc. may be used here in relation to elements of the disclosure, such elements should not be construed as being limited by these terms. The terms are only used to distinguish one element from other elements.

Additionally, it should be understood that the terms “comprises”, “comprising”, “includes” and/or “including”, when used in this application, mean the presence of the stated features, values, operations, elements and/or components, but do not exclude the presence or addition of one or more other features, values, operations, elements, components, and/or their groups.

In various embodiments of the disclosure, a “module” or “unit” may perform at least one function or operation and may be implemented in hardware, software, or a combination thereof. “Multiple modules” or “multiple blocks” may be implemented with at least one processor by integrating it with at least one module other than a “module” or “block” to be implemented with special-purpose hardware.

At least one of the plurality of modules may be implemented through an artificial intelligence (AI) model. A function associated with AI may be performed through a non-volatile memory, a volatile memory, and a processor.

The processor may include one or multiple processors. Meanwhile, one or more processors may be a general purpose processor such as a central processing unit (CPU), an application processor (AP) or the like, a graphics processor such as a graphics processing unit (GPU), an image processing unit (VPU), and/or an artificial intelligence (AI)-dedicated processor such as a neural processing unit (NPU). The disclosure is not limited to the above processors, and any processor capable of performing the desired task may be used.

The one or more of processors control the processing of the input data in accordance with a predefined operating rule or the AI model stored in the non-volatile memory and the volatile memory. The predetermined operating rule or the AI model is provided through training.

Here, being provided through learning means that, by applying a learning algorithm to a plurality of learning data, a predefined operating rule or AI model of a desired characteristic is made. The learning may be performed in a device itself which comprises AI according to an embodiment, and/or may be implemented through a separate server/system.

The AI model may consist of a plurality of neural network layers. Each layer has a plurality of weight values, and performs a layer operation through calculation of a previous layer and an operation of a plurality of weights. Examples of neural networks include, but are not limited to, convolutional neural network (CNN), deep neural network (DNN), recurrent neural network (RNN), restricted Boltzmann Machine (RBM), deep belief network (DBN), bidirectional recurrent deep neural network (BRDNN), generative adversarial networks (GAN), and deep Q-networks.

The learning algorithm is a method for training a predetermined target device (for example, an automatic device) using a plurality of learning data to cause, allow, or control the target device to make a determination or prediction. Examples of learning algorithms include, but are not limited to, supervised learning, unsupervised learning, semi-supervised learning, or reinforcement learning.

Hereinafter, various embodiments of the disclosure are described in more detail with reference to the accompanying drawings.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

In an embodiment, inaccuracy of output of a real sensor include a noise of the signal received by the real sensor. For example, the noise of the received by the real sensor may be caused by passing the signal through the transparent object, partial scattering of the signal, partial reflection of the signal from the transparent material, the influence of environment conditions and the relative position and movement of the object and the sensor in real space.

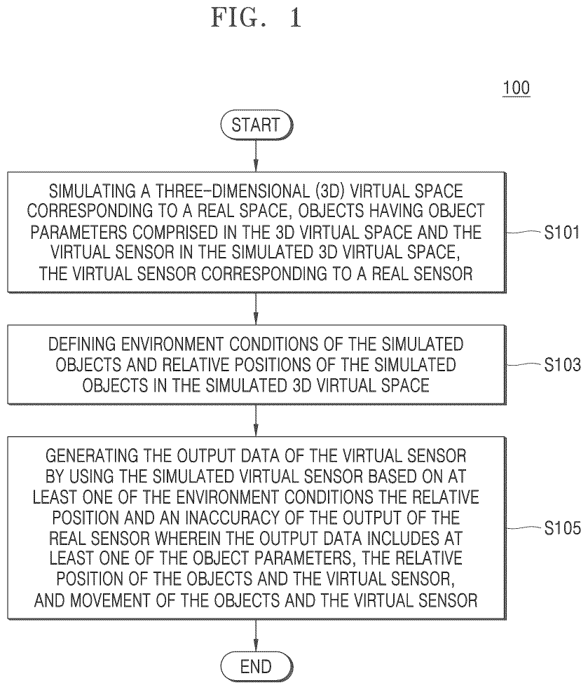

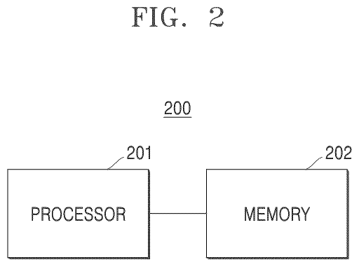

FIG. 1 is a flowchart of a method 100 for generating output data of a virtual sensor according to an embodiment of the disclosure. The method 100 for generating output data of a virtual sensor is executed by an electronic device 200, illustrated in FIG. 2, for generating output data of a virtual sensor.

The method 100 for generating output data of a virtual sensor comprises operations S101, S103 and S105.

In operation S101, the electronic device simulates a three-dimensional (3D) virtual space, objects having object parameters comprised in the 3D virtual space and the virtual sensor in the simulated 3D virtual space, the virtual sensor corresponding to a real sensor. A simulated 3D virtual space corresponds to a real space and comprises simulated objects, which are models of corresponding real objects. The simulated objects have the object parameters of the real objects.

In an embodiment, the simulated 3D virtual space depends on an application. For use in vehicles, a virtual space being an open space comprising roadways, roadway markings, traffic lights, road signs, buildings, pedestrian ways, vehicles, pedestrians, etc. is simulated. For use in robot vacuum cleaners, a virtual space being a room with corresponding objects, such as, for example, walls, floors, doors, wardrobes, chairs, a bed, etc. is simulated. It should be noted that the disclosure is not limited to the above examples of virtual spaces and objects, any virtual spaces can be simulated for various applications.

In operation S103, the electronic device defines environment conditions of the simulated objects and relative position of the simulated objects in the simulated 3D virtual space. In an embodiment, the environment conditions and the relative position of the simulated objects defined in the simulated 3D virtual space are the environments and the relative position of said objects in the real space, respectively. In an embodiment, the environment conditions in the simulated 3D virtual space corresponds to the environment conditions in the real space. For example, the environment conditions may include at least one of illumination, ambient temperature, humidity, atmospheric pressure, electromagnetic radiation, gas composition of the environment.

In an embodiment, the virtual sensor corresponding to a real sensor, a movement of a simulated virtual sensor in the simulated 3D virtual space and output data of the simulated virtual sensor obtained at different positions of the simulated virtual sensor in the simulated 3D virtual space are simulated based on propagation of signals in the real space and taking into account the object parameters, relative position and movement of the object and the sensor, the environment conditions, and the propagation of the signal in a path of which more than one object are positioned.

In the process of simulating the output data of the simulated virtual sensor in the simulated 3D virtual space, the movement of the virtual sensor and the objects of the simulated 3D virtual space relative to each other is simulated. Due to the movement of the virtual sensor and the objects of the simulated 3D virtual space relative to each other, the relative position and movement of the object and the sensor is changed.

The object parameters, the relative the position and movement of the object and sensor, environment conditions will be described below.

The simulation of the 3D virtual space, the virtual sensor, the movement of the simulated virtual sensor in the simulated 3D virtual space and the output data of the simulated virtual sensor performed in operations S101 may be performed by any simulator capable of simulating the virtual space. A particular simulator may or may not support real-time operation. It is preferable to use simulators operating in real time such as Gazebo, simulators based on Unreal Engine or Unity. It should be noted that the disclosure is not limited to the above examples of simulators operating in real time, and any simulators operating in real time can be used to operate in real time.

Each simulated output data of the simulated virtual sensor is provided with indications of the object for which the simulated output data of the simulated virtual sensor is obtained, the object parameters, the environment conditions and the relative position and movement of the object and the sensor obtained from the simulated 3D virtual space.

In operation S105, the electronic device generates the output data of the virtual sensor by using the simulated virtual sensor based on at least one of the environment conditions the relative position and an inaccuracy of the output of the real sensor. In an embodiment, electronic device generates the output data of the virtual sensor. In an embodiment, the output data includes at least one of the object parameters, the relative position of the objects and the virtual sensor, and movement of the objects and the virtual sensor. In an embodiment, the output data is generated by processing with a trained artificial intelligence (AI) model of the virtual sensor the simulated output data of the simulated virtual sensor, inaccuracies in output data of the real sensor and, for each simulated output data of the simulated virtual sensor, indications of the object for which the simulated output data of the simulated virtual sensor are obtained, the object parameters, the environment conditions and the relative position and movement of the object and the sensor obtained from the simulated 3D virtual space.

The AI model of the virtual sensor is trained using training data formed from the output data of the real sensor obtained for different real objects, and indications, for each output data of the real sensor, the object parameters, the environment conditions, the relative position and movement of the object and the sensor and the inaccuracy in the output data of the real sensor.

The AI model of the virtual sensor may be, for example, a convolutional neural network, a deep convolutional neural network, a recurrent neural network, a Bayesian neural network, a deep belief network, a Mixture Density Network, various generative adversarial networks, flow-based generative models, support vector machines, various autoencoders, probability models, attention models, regression models, etc. It should be noted that the AI model of the virtual sensor is not limited to the above AI means. For the AI model of any virtual sensor, any machine learning model can be used, based on providing the required accuracy and speed of operation.

The virtual sensor corresponds to the corresponding real sensor and may be one of a virtual lidar, a virtual RGB camera, a virtual RGBD camera, a virtual stereo camera, a virtual ToF camera, a virtual infrared camera, a virtual accelerometer, a virtual gyroscope, a virtual magnetometer, a virtual inertial measurement unit, a virtual inductive sensor, a virtual satellite navigation sensor, a virtual ultrasonic sensor, a virtual temperature sensor, a virtual pressure sensor, a virtual humidity sensor, a virtual gas sensor, a virtual light sensor and their combinations. The trained AI model of the virtual sensor corresponds to the model of the particular real sensor, whose output data was used to train the AI model of the virtual sensor.

For the AI models of the virtual lidar, the virtual accelerometer, the virtual gyroscope, the virtual magnetometer, the virtual inertial measurement unit, the virtual inductive sensor, the virtual satellite navigation sensor, the virtual ultrasonic sensor, the virtual temperature sensor, the virtual pressure sensor, the virtual humidity sensor, the virtual gas sensor, the virtual light sensor, it is preferable to use the regression model based on, for example, linear regression, polynomial regression, stepwise regression, decision tree, random forest, support vector machine, ridge regression, lasso regression, etc.

For the AI models of the virtual RGB camera, the virtual RGBD camera, the virtual stereo camera, the virtual ToF camera, the virtual infrared camera, it is preferable to use the generative adversarial network.

In the process of forming the training data, each real object among a plurality of real objects is positioned in a plurality of relative positions and movements of the object and the sensor. The output data of the real sensor is obtained under different environment conditions. Different real objects have different object parameters.

Each real object or simulated object is characterized by the object parameters. The object parameters of the simulated object correspond to the object parameters of the real object. The object parameters may include a material of the object and at least one of dimensions of the object, a shape of the object, a temperature of the object, a reflectivity, an absorptivity, a signal scattering coefficient.

The relative position and movement of the object and the sensor in the simulated 3D virtual space and the real space may include a distance from the sensor to the object, an orientation angle of the object relative to the sensor, a rotation speed of the object relative to the sensor, a relative speed between the sensor and the object, a relative acceleration between the sensor and the object.

The environment conditions in the simulated 3D virtual space corresponds to the environment conditions in the real space. The environment conditions may include at least one of illumination, ambient temperature, humidity, atmospheric pressure, electromagnetic radiation, gas composition of the environment.

In the process of forming the training data, a set of objects made of different materials such as metal, wood, fabric, leather, glass, mirror, plastic, etc. is selected. It should be noted that the disclosure is not limited to the listed materials, and any materials may be selected.

When receiving signals from each object and obtaining the output data of the real sensor, either the object or the real sensor is positioned at different distances from the sensor to the object, at different orientation angles of the object relative to the sensor. Furthermore, each object may be rotated with different rotation speeds and angular accelerations of the object relative to the sensor, the real sensor and/or the object may be moved relative to each other with different relative speeds between the sensor and the object and different relative accelerations between the sensor and the object. When receiving signals from each object and obtaining the output data of the real sensor, the environment conditions are changed as well.

In the process of forming the training data for each object, the signals from which the output data of the real sensor are obtained are received by the real sensor in all possible combinations of different environment conditions and different relative positions and movements of the object and the sensor.

In the training data, each output data of the real sensor is provided with the indications of the object parameters, the environment conditions, and the relative position and movement of the object and the sensor, and the inaccuracy of the output data of the real sensor.

In the case of a transparent object, such as an object made of glass or other transparent material, the real sensor may receive signals through the transparent object from an opaque object positioned behind the transparent object. For example, in the case of a lidar, the output data of the real sensor will be output as the distance from the lidar to the opaque object positioned behind the transparent object with the inaccuracy that includes the internal inaccuracy of the real sensor and the inaccuracy depending on the object parameters of the real object, the environment conditions and the relative position and movement of the object and the sensor in real space. In this case, the inaccuracy that depends on the object parameters of the real object, the environment conditions and the relative position and movement of the object and the sensor in real space is defined by the noise of the signal received by the real sensor. This noise of the signal received by the real sensor is caused by passing the signal through the transparent object, partial scattering of the signal, partial reflection of the signal from the transparent material, the influence of environment conditions and the relative position and movement of the object and the sensor in real space on the signal received by the real sensor. The example is given for lidar only, however, the disclosure is not limited to the above example and can be applied to any sensor that can receive signals through the transparent object. In this case, it will be obvious to a person skilled in the art based on the laws of physics, how to determine the noise of the signal received by any real sensor through the transparent object, and, therefore, to determine the inaccuracy in the output data of the real sensor caused by passing the signal received by the real sensor through the transparent object.

In the case of a real sensor that can receive signals from a transparent object, correct output data of the real sensor is set as the output data of the real sensor obtained for the transparent object, and the correct output data of the real sensor is provided with the object parameters of the transparent object, the environment conditions, and the relative position and movement of the object and the sensor. For example, in the case of the lidar, the correct output data of the real sensor for the transparent object is the distance from the lidar to the transparent object. The example is given for lidar only, however, the disclosure is not limited to the above example of the correct output data of the real sensor and can be applied to any sensor that can receive signals through the transparent object.

In the case of a reflective object, such as an object made of a mirror or other highly reflective material, the real sensor may receive signals from an opaque object reflected in the reflective object. For example, in the case of a lidar, the output data of a real sensor will be output as the distance from the lidar to the opaque object reflected in the reflective object with the inaccuracy defined by the internal inaccuracy of the real sensor and the inaccuracy depending on the object parameters of the real object, the environment conditions and the relative position and movement of the object and sensor in the real space. The inaccuracy depending on the object parameters of the real object, the environment conditions and the relative position and movement of the object and the sensor in the real space will depend on the signal noise of the signal received by the real sensor that is caused by signal scattering on the reflective object, the environment conditions and the relative position and movement of the object and the sensor. It should be noted that the lidar is given as example only, and the disclosure is not limited to the above example and can be applied to any sensor that can receive signals from reflective objects.

In the case of a real sensor that can receive signals from the reflective object, correct output data of the real sensor is set as the output data of the real sensor obtained for the reflective object, and the correct output data of the real sensor is provided with the object parameters, the environment conditions, and the relative position and movement of the object and the sensor. For example, in the case of the lidar, the correct output data of the real sensor is the distance from the lidar to the reflective object. The example is given for lidar only, however, the disclosure is not limited to the above example of the correct output data of the real sensor and can be applied to any sensor that can receive signals from the reflective object. In this case, it will be obvious to a person skilled in the art based on the laws of physics, how to determine the noise of the signal received by any real sensor from the reflective object, and, therefore, to determine the inaccuracy in the output data of the real sensor caused by passing the signal received by the real sensor from the reflective object.

For each output data of the real sensor, the inaccuracy of the output data of the real sensor is calculated. The inaccuracy of the output data of the real sensor includes the internal inaccuracy of the real sensor and the inaccuracy that depends on the object parameters of the real object, the environment conditions and the relative position and movement of the object and the sensor in the real space. The internal inaccuracy of the real sensor is known from a technical specification of the real sensor and is determined during the manufacture of the real sensor.

The inaccuracy of the output data of the real sensor is the deviation of the output data of the real sensor from the actual value measured by the real sensor. The inaccuracy of the output data of the real sensor is calculated by determining this deviation. The actual value measured by the real sensor can be obtained by calculating according to the laws of physics based on knowledge of the object parameters, the environment conditions and the relative position and movement of the object and sensor in the real space. The actual value measured by the real sensor can be a value obtained by a more precise sensor or measuring device, an average value of a set of measurements performed for the object under the same environment conditions and the relative position and movement of the object and the sensor in the real space, a value obtained by applying any other method/model for removing noise from the signal received by the real sensor. These methods for determining the deviation of the output data of the real sensor from the actual value measured by the real sensor can be applied to any real sensors.

For example, for the lidar, many measurements of the distance to the object can be performed under the same environment conditions and the relative position and movement of the object and the sensor in the real space. After that, the average value of these distance measurements is calculated as the actual value of the distance to the object. Then the calculated actual distance to the object is subtracted from the output data of the lidar to obtain the inaccuracy of the output data of the lidar. Furthermore, the actual value of the distance to the object can be measured with a more precise laser rangefinder or a tape measure. The example is given for lidar only, however, the disclosure is not limited to the above example and can be applied to any sensor.

The simulated output data of the simulated virtual sensor obtained in operation S101 is the accurate output data and does not fully match with the output data of the real sensor, because the simulated output data of the simulated virtual sensor does not have the inaccuracy of the output data of the real sensor. The inaccuracies of the output data of the real sensor are included in the AI model of the virtual sensor so that the inaccuracies of the output data of the real sensor are included in the output data of the virtual sensor generated by the AI model of the virtual sensor. Inclusion of the inaccuracies of the output data of the real sensor in the generated output data of the virtual sensor results in a more realistic output data of the virtual sensor closer to the output data of the real sensor. Each the inaccuracy of the output data of the real sensor is associated with the output data of the real sensor for which the inaccuracy of the output data of the real sensor is calculated.

By training the AI model of the virtual sensor on data from the real sensor and including the inaccuracies of the output data of the real sensor in the AI model of the virtual sensor, it is possible to generate more realistic output data of the virtual sensor closer to the output data of the real sensor.

The use of simulators operating in real time allows the trained AI model of the virtual sensor to generate the output data of the virtual sensor in real time.

FIG. 2 is a block diagram of the electronic device 200 for generating output data of a virtual sensor according to an embodiment of the disclosure. The electronic device 200 for generating output data of the virtual sensor is capable of performing the method 100 for generating output data of the virtual sensor.

The electronic device 200 for generating output data of the virtual sensor includes processor 201 and a memory 202. The memory stores the trained AI model of the virtual sensor and instructions that, when executed by the at least one processor, cause the at least one processor to perform the method for generating output data of the virtual sensor according to any embodiment.

The processor 201 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The processor 201 may be a central processing unit (CPU), an application processor (AP) or the like, or a dedicated processor such as, for example, a neural processing unit (NPU) or the like.

In an embodiment, the processor 201 can write data to memory 202 or read data stored in memory 202, In particular, data can be processed according to predefined operation rules or artificial intelligence models by executing a program or at least one instruction stored in the memory 202.

The memory 202 may be any of volatile memory or non-volatile memory. In an embodiment, the memory 202 may comprise volatile memory, such as random access memory (RAM), for use as temporary memory, and/or non-volatile memory such as Flash, read only memory (ROM), or electrically erasable programmable ROM (EEPROM), for storing data, programs, or instructions, for example.

The output data generated by the AI model of the virtual sensor according to the disclosure can be used for the electronic device 200. In an embodiment, the electronic device 200 includes virtual/augmented reality devices, navigation devices, simultaneous localization and mapping (SLAM) devices, object recognition devices, and etc. In addition, the output data generated by the AI model of the virtual sensor according to the disclosure can be used as training data for various AI model-based devices, such as robot control devices, drone control devices, vehicle control devices, navigation devices, SLAM devices, object recognition devices, etc. It should be noted that the AI model-based devices are not limited to the above devices and can be any AI model-based devices that process output data of real sensors.

The AI model-based devices processing the output data of the real sensors can be trained using the output data generated by the AI model of the virtual sensor according to the disclosure to function properly in a real environment. Otherwise, if such devices are trained using the simulated output data of the simulated virtual sensor known in related art without taking into account the data of the real sensor and their inaccuracies, then the output data of these devices will contain errors due to the difference between the output data of the real sensor and the output data of the virtual sensor.

The applicant compared results of operation of a) an AI model-based device processing the output data of the real sensors and trained on the simulated output data of the simulated virtual sensor (hereinafter the device trained on the simulated output data), b) an AI model-based device processing the output data of the real sensors and trained on the output data of the virtual sensor according to the disclosure (hereinafter the device based on the disclosure), c) a non-AI reference device processing the output data of the real sensors. Intel RealSense Depth Camera D435 was used as the reference device.

In an embodiment, results of displaying colors in a generated image were compared. The image was generated by processing a test image of colors in the form of a set of squares of different colors. The test image of colors was processed by each of the above devices, and the results of processing the test image of colors with the Intel RealSense Depth Camera D435 were compared with the results of processing the test image of colors with the device trained on the simulated output data and the device based on the disclosure. The agreement between the processing results of the Intel RealSense Depth Camera D435 and the processing results of the device trained on the simulated output data is 40%. The agreement between the processing results of the Intel RealSense Depth Camera D435 and the processing results of the device based on the disclosure is 90%. Apparently, the device based on the disclosure provides data that is closer to that provided by the Intel RealSense Depth Camera D435 than the device trained on the simulated output data.

In an embodiment, accuracies of object detection/recognition results obtained by the Intel RealSense Depth Camera D435, the device based on the disclosure, and the device trained on the simulated output data were compared. The accuracies of object detection/recognition results are shown in a Table 1.

TABLE 1

| | Accuracy of object definition/recognition results | | |
|---|---|---|---|
| | Device trained | Intel RealSense | Device |
| | on the simulated | Depth | based on the |
| Object | output data | Camera D435 | disclosure |
| All | 66.5% | 67.1% | 67.5% |
| Chair | 50.7% | 37.8% | 45.5% |
| Couch | 92.3% | 94.8% | 96.6% |
| Table | 67.3% | 73.4% | 68.8% |

The accuracies of object detection/recognition results cited in the Table 1 show that the device based on the disclosure provides data that is closer to that of the Intel RealSense Depth Camera D435 than a device trained on the simulated output data.

In an embodiment, accuracies of results of detection of distances to objects obtained by the Intel RealSense Depth Camera D435, the device based on disclosure, and the device trained on the simulated output data were compared. The accuracy of results of detection of distances to objects obtained by the Intel RealSense Depth Camera D435 is 90%. The accuracy of results of detection of distances to objects obtained by the device based on the disclosure is 80%. The accuracy of results of detection of distances to objects obtained by the device trained on the simulated output data is 30%. Apparently, the device based on the disclosure provides data that is closer to that provided by the Intel RealSense Depth Camera D435 than the device trained on the simulated output data.

AI models that process the output data of the real sensors are selected depending on the tasks performed by the AI model-based devices.

The disclosure can be applied to the development of various robots, vehicles equipped with an automatic control system, navigation devices, devices for generating data of 3D spaces, drones, object recognition devices, etc.

The above descriptions of the embodiments are illustrative, and configuration modifications and implementations are within the scope of the description. For example, although the embodiments of the disclosure have been described in general in connection with FIGS. 1 and 2 the descriptions given are only examples of the disclosed aspects. Although the subject matter is described in a language characteristic of structural features or methodological operations, it is clear that the subject matter is not necessarily limited by the specific features or operations described above. Moreover, the specific features and operations described above are disclosed as embodiments of the claims.

Accordingly, it is assumed that the scope of the embodiments of the disclosure is limited only by the following claims.

In an embodiment, a method performed by an electronic device for generating the output data of the virtual sensor is provided. The method includes simulating, by the electronic device, a three-dimensional (3D) virtual space corresponding to a real space, simulating, by the electronic device, the virtual sensor in the simulated 3D virtual space, the virtual sensor corresponding to a real sensor, and generating, by the electronic device, output data of the virtual sensor based on the simulated virtual sensor, wherein the simulated 3D virtual space comprises simulated objects having object parameters, wherein, in the simulated 3D virtual space, environment conditions of the simulated objects and relative positions of the simulated objects are defined, wherein the simulated objects are models of corresponding real objects in the real space, wherein the defined environment conditions of the simulated objects correspond to environment conditions of the real space, wherein the defined relative position of the simulated objects correspond to relative positions of the corresponding real objects, wherein the simulating of the virtual sensor in the simulated 3D virtual space includes moving the simulated virtual sensor in the simulated 3D virtual space and simulating output data of the simulated virtual sensor obtained at different positions of the simulated virtual sensor in the simulated 3D virtual space, wherein the simulated output data is based on propagation of signals in the real space, the object parameters, relative position and movement of the object and the sensor, the environment conditions, and the propagation of the signal in a path of which more than one object are positioned, wherein the generating of the output data of the virtual sensor includes processing with a trained artificial intelligence (AI) model of the virtual sensor the simulated output data of the simulated virtual sensor, inaccuracies in output data of the real sensor and, for each simulated output data of the simulated virtual sensor, indications of the object for which the simulated output data of the simulated virtual sensor are obtained, the object parameters, the environment conditions and the relative position and movement of the object and the sensor obtained from the simulated 3D virtual space, and wherein the AI model of the virtual sensor is trained using training data formed from the output data of the real sensor obtained for different real objects, and indications, for each output data of the real sensor, the object parameters, the environment conditions, the relative position and movement of the object and the sensor and the inaccuracy in the output data of the real sensor.

In an embodiment, the virtual sensor includes at least one of a virtual lidar, a virtual red green blue (RGB) camera, a virtual red green blue red green blue depth (RGBD) camera, a virtual stereo camera, a virtual time of flight (ToF) camera, a virtual infrared camera, a virtual accelerometer, a virtual gyroscope, a virtual magnetometer, a virtual inertial measurement unit, a virtual inductive sensor, a virtual satellite navigation sensor, a virtual ultrasonic sensor, a virtual temperature sensor, a virtual pressure sensor, a virtual humidity sensor, a virtual gas sensor or a virtual light sensor, and wherein the trained AI model of the virtual sensor corresponds to the model of the corresponding real sensor.

In an embodiment, the object parameters correspond to the parameters of the real object and include a material of the object and at least one of dimensions of the object, a shape of the object, a temperature of the object, a reflectivity, an absorptivity, or a signal scattering coefficient.

In an embodiment, the relative position and movement of the object and the sensor in the simulated 3D virtual space and the real space includes a distance from the sensor to the object, an orientation angle of the object relative to the sensor, a rotation speed of the object relative to the sensor, a relative speed between the sensor and the object, a relative acceleration between the sensor and the object.

In an embodiment, the environment conditions include at least one of illumination, ambient temperature, humidity, atmospheric pressure, electromagnetic radiation, or gas composition of the environment.

In an embodiment, when forming training data, each real object among a plurality of real objects is positioned in a plurality of relative positions and movements of the object and the sensor, different real objects having different object parameters, wherein the output data of the real sensor is obtained under different environment conditions, wherein, for each output data of the real sensor, the inaccuracy of the output data of the real sensor is calculated, which includes an internal inaccuracy of the real sensor and an inaccuracy depending on the object parameters of the real object, the environment conditions and the relative position and movement of the object and the sensor in the real space, wherein the inaccuracies of the output data of the real sensor are included in the AI model of the virtual sensor, and wherein each inaccuracy of the output data of the real sensor is associated with the output data of the real sensor for which the inaccuracy of the output data of the real sensor is calculated.

In an embodiment, an electronic device for generating the output data of the virtual sensor is provided. The electronic device includes memory storing one or more computer programs and a trained AI model of a virtual sensor, and one or more processors, wherein the one or more computer programs include computer-executable instructions that, when executed by the one or more processors, cause the electronic device to: simulate a 3D virtual space corresponding to a real space, simulate the virtual sensor in the simulated 3D virtual space, the virtual sensor corresponding to a real sensor, and generate output data of the virtual sensor based on the simulated virtual sensor, wherein the simulated 3D virtual space comprises simulated objects having object parameters, wherein, in the simulated 3D virtual space, environment conditions of the simulated objects and relative positions of the simulated objects are defined, wherein the simulated objects are models of corresponding real objects in the real space, wherein the defined environment conditions of the simulated objects correspond to environment conditions of the real space, wherein the defined relative position of the simulated objects correspond to relative positions of the corresponding real objects, wherein, to simulate the virtual sensor in the simulated 3D virtual space, the one or more computer programs further include computer-executable instructions that, when executed by the one or more processors, cause the electronic device to move the simulated virtual sensor in the simulated 3D virtual space and simulate output data of the simulated virtual sensor obtained at different positions of the simulated virtual sensor in the simulated 3D virtual space, wherein the simulated output data is based on propagation of signals in the real space, the object parameters, relative position and movement of the object and the sensor, the environment conditions, and the propagation of the signal in a path of which more than one object are positioned, wherein, to generate the output data of the virtual sensor, the one or more computer programs further include computer-executable instructions that, when executed by the one or more processors, cause the electronic device to process with a trained AI model of the virtual sensor the simulated output data of the simulated virtual sensor, inaccuracies in output data of the real sensor and, for each simulated output data of the simulated virtual sensor, indications of the object for which the simulated output data of the simulated virtual sensor are obtained, the object parameters, the environment conditions and the relative position and movement of the object and the sensor obtained from the simulated 3D virtual space, and wherein the AI model of the virtual sensor is trained using training data formed from the output data of the real sensor obtained for different real objects, and indications, for each output data of the real sensor, the object parameters, the environment conditions, the relative position and movement of the object and the sensor and the inaccuracy in the output data of the real sensor.

In an embodiment, one or more non-transitory computer-readable storage media storing one or more computer programs including computer-executable instructions that, when executed by one or more processors of an electronic device, cause the electronic device to perform operations are provided. The operations include simulating, by the electronic device, a 3D virtual space corresponding to a real space, simulating, by the electronic device, a virtual sensor in the simulated 3D virtual space, the virtual sensor corresponding to a real sensor, and generating, by the electronic device, output data of the virtual sensor based on the simulated virtual sensor, wherein the simulated 3D virtual space comprises simulated objects having object parameters, wherein, in the simulated 3D virtual space, environment conditions of the simulated objects and relative positions of the simulated objects are defined, wherein the simulated objects are models of corresponding real objects in the real space, wherein the defined environment conditions of the simulated objects correspond to environment conditions of the real space, wherein the defined relative position of the simulated objects correspond to relative positions of the corresponding real objects, wherein the simulating of the virtual sensor in the simulated 3D virtual space includes moving the simulated virtual sensor in the simulated 3D virtual space, and simulating output data of the simulated virtual sensor obtained at different positions of the simulated virtual sensor in the simulated 3D virtual space, wherein the simulated output data is based on propagation of signals in the real space, the object parameters, relative position and movement of the object and the sensor, the environment conditions, and the propagation of the signal in a path of which more than one object are positioned, wherein the generating of the output data of the virtual sensor includes processing, with a trained AI model of the virtual sensor, the simulated output data of the simulated virtual sensor, inaccuracies in output data of the real sensor and, for each simulated output data of the simulated virtual sensor, indications of the object for which the simulated output data of the simulated virtual sensor are obtained, the object parameters, the environment conditions and the relative position and movement of the object and the sensor obtained from the simulated 3D virtual space, and wherein the AI model of the virtual sensor is trained using training data formed from the output data of the real sensor obtained for different real objects, and indications, for each output data of the real sensor, the object parameters, the environment conditions, the relative position and movement of the object and the sensor and the inaccuracy in the output data of the real sensor.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A method performed by an electronic device for generating output data of a virtual sensor, the method comprising:
simulating, by the electronic device, a three-dimensional (3D) virtual space corresponding to a real space, objects having object parameters comprised in the 3D virtual space and the virtual sensor in the simulated 3D virtual space, the virtual sensor corresponding to a real sensor;
defining, by the electronic device, environment conditions of the simulated objects and relative position of the simulated objects in the simulated 3D virtual space; and
generating, by the electronic device, the output data of the virtual sensor by using the simulated virtual sensor based on at least one of the environment conditions the relative position and an inaccuracy of the output of the real sensor,
wherein the output data includes at least one of the object parameters, the relative position of the objects and the virtual sensor, and movement of the objects and the virtual sensor.

2. The method according to claim 1, wherein the simulated objects are models of corresponding real objects in the real space,
wherein the defined environment conditions of the simulated objects correspond to the environment conditions of the real space,
wherein the defined relative position of the simulated objects correspond to relative position of the corresponding real objects.

3. The method according to claim 1, wherein the simulating of the virtual sensor in the simulated 3D virtual space comprises:
moving the simulated virtual sensor in the simulated 3D virtual space; and
simulating an output of the simulated virtual sensor obtained at different positions of the simulated virtual sensor in the simulated 3D virtual space, wherein the simulated output is based on propagation of signals in the real space, the object parameters, relative position and movement of the object and the virtual sensor, the environment conditions, and the propagation of the signal in a path of which more than one object are positioned.

4. The method according to claim 1, wherein the generating of the output data of the virtual sensor comprises processing, with a trained artificial intelligence (AI) model of the virtual sensor, the simulated output of the simulated virtual sensor, the inaccuracy in output of the real sensor and, for each simulated output of the simulated virtual sensor, indications of the object for which the simulated output of the simulated virtual sensor are obtained, the object parameters, the environment conditions and the relative position and movement of the object and the virtual sensor obtained from the simulated 3D virtual space.

5. The method according to claim 4, wherein the AI model of the virtual sensor is trained using training data formed from the output of the real sensor obtained for different real objects, and indications, for each output of the real sensor, the object parameters, the environment conditions, the relative position and movement of the object and the virtual sensor and the inaccuracy of the output of the real sensor.

6. The method according to claim 1, wherein the virtual sensor includes at least one of a virtual lidar, a virtual red green blue (RGB) camera, a virtual red green blue depth (RGBD) camera, a virtual stereo camera, a virtual time of flight (ToF) camera, a virtual infrared camera, a virtual accelerometer, a virtual gyroscope, a virtual magnetometer, a virtual inertial measurement unit, a virtual inductive sensor, a virtual satellite navigation sensor, a virtual ultrasonic sensor, a virtual temperature sensor, a virtual pressure sensor, a virtual humidity sensor, a virtual gas sensor or a virtual light sensor, and
wherein a trained artificial intelligence (AI) model of the virtual sensor corresponds to a model of the corresponding real sensor.

7. The method according to claim 1, wherein the object parameters correspond to the parameters of a real object and include a material of the object and at least one of dimensions of the object, a shape of the object, a temperature of the object, a reflectivity, an absorptivity, or a signal scattering coefficient.

8. The method according to claim 1, wherein the relative position and movement of the object and the virtual sensor in the simulated 3D virtual space and the real space includes a distance from the virtual sensor to the object, an orientation angle of the object relative to the virtual sensor, a rotation speed of the object relative to the virtual sensor, a relative speed between the virtual sensor and the object, a relative acceleration between the virtual sensor and the object.

9. The method according to claim 1, wherein the environment conditions include at least one of illumination, ambient temperature, humidity, atmospheric pressure, electromagnetic radiation, or gas composition of the environment.

10. The method according to claim 1,
wherein, when forming training data, each real object among a plurality of real objects is positioned in a plurality of relative position and movement of the object and the virtual sensor, different real objects having different object parameters,
wherein the output of the real sensor is obtained under different environment conditions,
wherein, for each output of the real sensor, the inaccuracy of the output of the real sensor is calculated, which includes an internal inaccuracy of the real sensor and an inaccuracy depending on the object parameters of the real object, the environment conditions and the relative position and movement of the object and the virtual sensor in the real space,
wherein the inaccuracy of the output of the real sensor are included in an artificial intelligence (AI) model of the virtual sensor, and
wherein each inaccuracy of the output of the real sensor is associated with the output of the real sensor for which the inaccuracy of the output of the real sensor is calculated.

11. An electronic device for generating output data of a virtual sensor, the electronic device comprising:
memory storing one or more computer programs and a trained artificial intelligence (AI) model of the virtual sensor; and
one or more processors,
wherein the one or more computer programs include computer-executable instructions that, when executed by the one or more processors, cause the electronic device to:
simulate a three-dimensional (3D) virtual space corresponding to a real space, objects having object parameters comprised in the 3D virtual space and the virtual sensor in the simulated 3D virtual space, the virtual sensor corresponding to a real sensor,
define environment conditions of the simulated objects and relative position of the simulated objects in the simulated 3D virtual space, and
generate output data of the virtual sensor by using the simulated virtual sensor based on at least one of the environment conditions the relative position and an inaccuracy of the output of the real sensor,
wherein the output data includes at least one of the object parameters, the relative position of the objects and the virtual sensor, and movement of the objects and the virtual sensor.

12. The electronic device of claim 11, wherein the simulated objects are models of corresponding real objects in the real space,
wherein the defined environment conditions of the simulated objects correspond to environment conditions of the real space,
wherein the defined relative position of the simulated objects correspond to relative position of the corresponding real objects.

13. The electronic device of claim 11, wherein, to simulate the virtual sensor in the simulated 3D virtual space, the one or more computer programs further include computer-executable instructions that, when executed by the one or more processors, cause the electronic device to:
move the simulated virtual sensor in the simulated 3D virtual space, and
simulate output data of the simulated virtual sensor obtained at different positions of the simulated virtual sensor in the simulated 3D virtual space, wherein the simulated output data is based on propagation of signals in the real space, the object parameters, relative position and movement of the object and the virtual sensor, the environment conditions, and the propagation of the signal in a path of which more than one object are positioned.

14. The electronic device of claim 11, wherein, to generate the output data of the virtual sensor, the one or more computer programs further include computer-executable instructions that, when executed by the one or more processors, cause the electronic device to process, with the trained AI model of the virtual sensor, the simulated output of the simulated virtual sensor, the inaccuracy in output of the real sensor and, for each simulated output of the simulated virtual sensor, indications of the object for which the simulated output of the simulated virtual sensor are obtained, the object parameters, the environment conditions and the relative position and movement of the object and the virtual sensor obtained from the simulated 3D virtual space.

15. The electronic device of claim 11, wherein the AI model of the virtual sensor is trained using training data formed from the output data of the real sensor obtained for different real objects, and indications, for each output data of the real sensor, the object parameters, the environment conditions, the relative position and movement of the object and the virtual sensor and the inaccuracy of the output data of the real sensor.

16. The electronic device of claim 11,
wherein the virtual sensor includes at least one of a virtual lidar, a virtual red green blue (RGB) camera, a virtual red green blue depth (RGBD) camera, a virtual stereo camera, a virtual time of flight (ToF) camera, a virtual infrared camera, a virtual accelerometer, a virtual gyroscope, a virtual magnetometer, a virtual inertial measurement unit, a virtual inductive sensor, a virtual satellite navigation sensor, a virtual ultrasonic sensor, a virtual temperature sensor, a virtual pressure sensor, a virtual humidity sensor, a virtual gas sensor or a virtual light sensor, and
wherein the trained AI model of the virtual sensor corresponds to the model of the corresponding real sensor.

17. The electronic device of claim 11, wherein the object parameters correspond to the parameters of a real object and include a material of the object and at least one of dimensions of the object, a shape of the object, a temperature of the object, a reflectivity, an absorptivity, or a signal scattering coefficient.

18. The electronic device of claim 11, wherein the relative position and movement of the object and the virtual sensor in the simulated 3D virtual space and the real space includes a distance from the virtual sensor to the object, an orientation angle of the object relative to the virtual sensor, a rotation speed of the object relative to the virtual sensor, a relative speed between the virtual sensor and the object, a relative acceleration between the virtual sensor and the object.

19. The electronic device of claim 11, wherein the environment conditions include at least one of illumination, ambient temperature, humidity, atmospheric pressure, electromagnetic radiation, or gas composition of the environment.

20. One or more non-transitory computer-readable storage media storing one or more computer programs including computer-executable instructions that, when executed by one or more processors of an electronic device, cause the electronic device to perform the method of claim 1.
